(19) United States
(12) Patent Application Publication
(10) Pub. No.: US 2008/0003795 A1
(43) Pub. Date: Jan. 3, 2008

(54) Method of manufacturing a pattern

(75) Inventor: Takashi Kojima, Kawasaki (JP)

Correspondence Address: Patrick G. Burns, Esq.;GREER, BURNS & CRAIN, LTD., Suite 2500, 300 South Wacker Dr., Chicago, IL, 60606, US

(73) Assignee: FUJITSU LIMITED

(21) Appl. No.: 11/591,951

(22) Filed: Nov. 1, 2006

(30) Foreign Application Priority Data
Jul. 3, 2006 (JP) 2006-182959

(51) Int. Cl. H01L 21/44

(52) U.S. Cl. 438/597

(57) ABSTRACT

A method of manufacturing a pattern can control the shape of a resist mask that forms read terminals in a predetermined pattern with high precision, so that the formation precision of the read terminals is improved and the manufacturing yield of the magnetic head is improved. The method includes: a step of forming a layer to be patterned on a substrate; a step of forming a first mask layer on the layer to be patterned; a step of forming a second mask layer, which has a lower etching rate during a dry etching process than the first mask layer, on the first mask layer; a step of exposing and developing the second-mask layer to form the second mask layer in a predetermined shape; and a step of removing exposed parts of the first mask layer that are exposed from the second mask layer by dry etching and dry etching a part of the first mask layer below the second mask layer from sides thereof to form a column part in the first mask layer that is narrower than the second mask, thereby forming a mask with overhanging parts.

### BACKGROUND OF THE INVENTION

1. Field of the Invention

The present invention relates to a method of manufacturing a pattern of a predetermined shape from a layer formed on a substrate, and in more detail to a method of manufacturing a pattern of a predetermined shape such as the shape of a magnetoresistive effect element used in the read head of a magnetic head.

2. Related Art

As shown in FIG. 2A, during a process that forms a magnetoresistive effect element, after an element layer 10 that will become a read element has been formed on the surface of a work 5, a resist pattern 6 which has overhanging parts 6a formed in the side surfaces thereof is formed on the surface of the element layer 10. The resist pattern 6 is used as a mask when patterning the element layer 10 into predetermined patterns (widths) by ion milling to form a read terminal 10a.

The overhanging parts 6a are provided in the side surfaces of the resist pattern 6 to restrict the area irradiated with ions during the ion milling so that the side surfaces of the read terminal 10a are formed as the required inclined surfaces (see FIG. 2B) and to make it easy to remove any foreign matter that adheres to the surface of the resist pattern 6 together with the resist pattern 6 during a lift-off process.

As shown in FIGS. 2A and 2B, one known method of forming the resist pattern 6 with the overhanging parts 6a forms two layers of resist materials with different etching rates and uses the difference in etching rates when exposing and developing the resist to form overhanging parts. That is, if the etching rate of the resist material on the lower layer is higher (i.e., faster) than the etching rate of the resist material on the upper layer, when the resist is etched after being exposed, the resist material on the lower layer will be etched faster than the upper layer, resulting in the formation of the resist pattern 6 with the overhanging parts 6a.

### Patent Document 1

Japanese Laid-Open Patent Publication No. 2003-92442

### SUMMARY OF THE INVENTION

However, with a method that forms a resist pattern like that shown in FIGS. 2A and 2B by using a difference in etching rates when wet etching resist materials, it is difficult to precisely control the pattern. As the recording density of recording media increases and read terminals 10a become increasingly narrow, this method ceases to be suitable. For example, in a resist pattern 6 for patterning a read terminal, the main part of the pattern is only around 120 nm wide, and since the column part that supports such main part is extremely narrow, there is the problem of the formed resist pattern 6 collapsing if the column part is excessively etched by the wet etching.

The present invention was conceived to solve the problem described above and it is an object of the present invention to provide a method of manufacturing a pattern that can form a mask with high precision when forming a precise pattern, such as when forming the read terminals of a magnetic head in a predetermined pattern, and can form a suitable pattern even when forming an extremely fine pattern such as read terminals.

To achieve the stated object, a method of manufacturing a pattern according to the present invention includes: a step of forming a layer to be patterned on a substrate; a step of forming a first mask layer on the layer to be patterned; a step of forming a second mask layer, which has a lower etching rate during a dry etching process than the first mask layer, on the first mask layer; a step of exposing and developing the second mask layer to form the second mask layer in a predetermined shape; and a step of removing exposed parts of the first mask layer that are exposed from the second mask layer by dry etching and dry etching a part of the first mask layer below the second mask layer from sides thereof to form a column part in the first mask layer that is narrower than the second mask layer, thereby forming a mask with overhanging parts.

Also, by forming the first mask layer of resin and forming the second mask layer of a resist material including silicon, it is possible to produce a clear difference in etching rates between the first mask layer and the second mask layer and to reliably form a mask with overhanging parts.

Also, by forming a protective layer, which is composed of a material that suppresses etching of the column part made of the first mask layer during the dry etching process, as an uppermost layer of the layer to be patterned, it is possible to suppress further etching of the column part during the dry etching process, thereby facilitating the operation during the dry etching process and making it possible to form a mask with no fluctuations in shape.

Another method of manufacturing a pattern according to the present invention includes: a step of forming a layer to be patterned, whose surface is made of ruthenium, on a substrate; a step of forming a first mask layer on the layer to be patterned; a step of forming a second mask layer, which has a lower etching rate than the first mask layer, on the first mask layer; a step of exposing and developing the second mask layer to form the second mask layer in a predetermined shape; and a step of removing exposed parts of the first mask layer that are exposed from the second mask layer by etching and etching a part of the first mask layer below the second mask layer from sides thereof to form a column part in the first mask layer that is narrower than the second mask layer, thereby forming a mask with overhanging parts.

With the method of manufacturing a pattern according to the present invention, by providing a first mask layer and a second mask layer with different etching rates during the dry etching process and forming a mask by dry etching, compared to conventional wet etching, it is possible to form the mask with higher precision, to suppress fluctuations in the shape of the mask and form a pattern with high precision, and to improve the manufacturing yield of products.

### BRIEF DESCRIPTION OF THE DRAWINGS

The aforementioned and other objects and advantages of the present invention will become apparent to those skilled in the art upon reading and understanding the following detailed description with reference to the accompanying drawings.

In the drawings:

FIGS. 1A to 1E are diagrams useful in explaining manufacturing steps of a magnetoresistive effect element according to a method of manufacturing a pattern according to the present invention; and

FIGS. 2A and 2B are diagrams useful in explaining a method of forming read terminals by forming a resist pattern on an element layer.

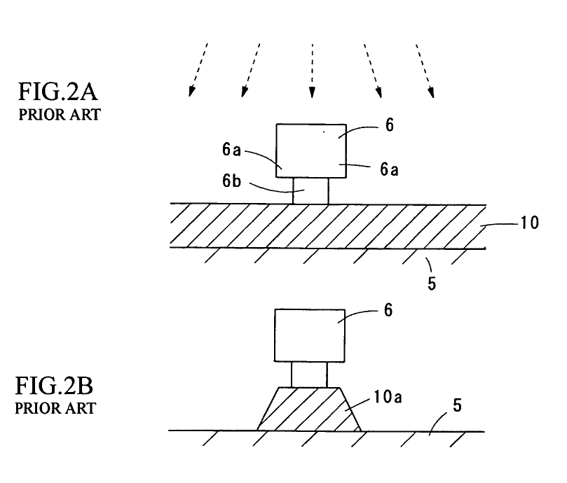

### DESCRIPTION OF THE PREFERRED EMBODIMENTS

Preferred embodiments of the present invention will now be described in detail with reference to the attached drawings.

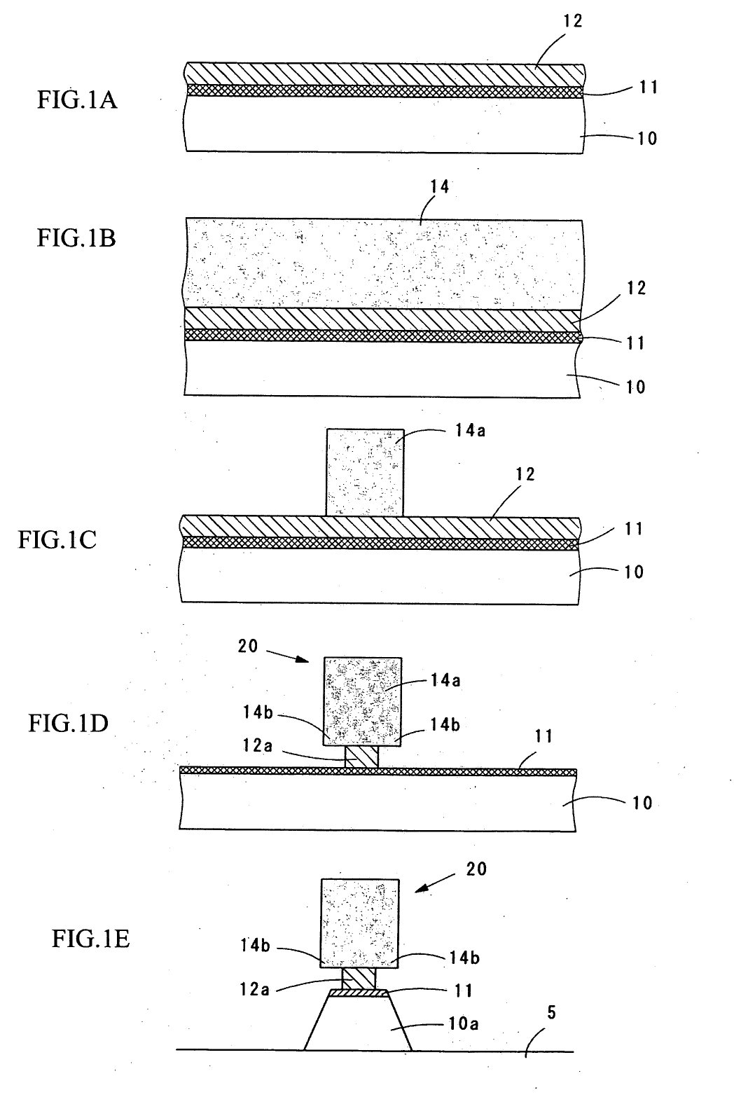

As an embodiment of a method of manufacturing a pattern according to the present invention, FIGS. 1A to 1E show a process that forms an element layer 10 as a layer to be patterned on the surface of a work and then forms a resist pattern as a mask for patterning the element layer 10 by ion milling during the manufacturing of a magnetoresistive effect element.

FIG. 1A shows a state where the element layer 10 has been formed and then an antireflection coating 12 made of resin has been formed as a first mask layer on the surface of the element layer 10. Note that the element layer 10 is formed by laminating a magnetic film, an insulating film, and the like for constructing read terminals. The multilayer construction of the element layer 10 will differ according to whether the element layer 10 is for a GMR element, a TMR element, or the like. Although the present invention does not depend on the construction of the element layer 10, the material of a protective layer 11 formed on the surface of the element layer 10 plays an important role in the formation of a suitable pattern in a resist mask.

The antireflection coating 12 that covers the surface of the protective layer 11 is used to stop reflection when an exposing operation is carried out on a resist material formed on the antireflection coating 12, and is formed using a material with a faster (i.e., higher) etching rate for dry etching than the resist material. The antireflection coating 12 is formed by coating the surface of the substrate with an antireflection resin material. In the present embodiment, the antireflection coating 12 has a thickness of 60 to 70 nm.

FIG. 1B shows a state where the surface of the antireflection coating 12 has been coated with the resist material to form a resist layer 14 as a second mask layer. The thickness of the resist layer 14 is around 300 nm.

In the present embodiment, a resist material including silicon was used to prevent the resist from being eroded by the dry etching carried out as a later process. By setting the etching rate during dry etching of the resist layer at a low rate and setting the etching rate during dry etching of the antireflection coating 12 below the resist layer 14 at a higher rate than the resist layer 14, it is possible to construct the mask layer that covers the protective layer 11 of two layers that have different etching rates during dry etching.

Next, exposing and developing operations are carried out on the resist layer 14 to form a resist pattern 14a on the surface of the work (see FIG. 1C). Here, a large number of magnetic heads (read terminals) are fabricated on one work. During the exposing and developing operations, the resist pattern 14a is formed in accordance with the respective element positions on the work. FIG. 1C shows a state where a resist pattern 14a that is rectangular in cross section has been formed at one element formation position on the work. Since the antireflection coating 12 is not eroded by the exposing and developing operations carried out on the resist layer 14, the antireflection coating 12 remains on the surface of the protective layer 11.

FIG. 1D shows a state where in the characteristic process of the present embodiment, the antireflection coating 12 has been etched by dry etching to form a column part 12a composed of the antireflection coating 12 below the resist pattern 14a, thereby forming a resist mask 20.

The dry etching removes exposed parts of the antireflection coating 12 that are not covered by the resist pattern 14a and also etches the antireflection coating 12 situated below the resist pattern 14a from the side surfaces thereof, thereby shaping the antireflection coating 12 into a column part that is narrower than the pattern width of the resist pattern 14a. By doing so, overhanging parts 14b are formed in the side surfaces of the resist pattern 14a.

The overhanging parts 14b formed in the side surfaces of the resist pattern 14a are formed by controlling the etching time for which the antireflection coating 12 is etched by dry etching. If the etching time is increased, the column part 12a of the antireflection coating 12 becomes narrower and the overhanging parts 14b overhang by a greater distance, while if the etching time is decreased, the column part 12a becomes thicker and the overhanging parts 14b overhang by a shorter distance.

In the present embodiment, the antireflection coating 12 is etched by an O₂ plasma process. Such dry etching is isotropic, so that the etching of the antireflection coating 12 situated below the resist pattern 14a proceeds from the side surfaces thereof without the resist pattern 14a hardly being etched.

According to this method of forming the resist mask 20 by etching the antireflection coating 12 by dry etching, by controlling the etching time, it is possible to control the form of the overhanging parts 14b of the resist mask 20. Note that in the present embodiment, the etching time of the dry etching was around 200 seconds.

In this dry etching process, the antireflection coating 12 is etched and as the exposed parts of the antireflection coating 12 are etched, the protective layer 11 therebelow is also etched. The protective layer 11 is scattered by the dry etching and becomes deposited on the column part 12a of the antireflection coating 12 that has been etched to become column-shaped and on the outer surfaces of the resist pattern 14a. The present inventors discovered that when the protective layer 11 is composed of a material that is difficult to etch in the O₂ plasma process, the protective layer 11 becomes deposited on the outer surfaces of the column part 12a of the antireflection coating 12 and suppresses further etching of the column part 12a.

That is, after the antireflection coating 12 has been etched and removed by dry etching, once etching of the protective layer 11 starts, the material of the protective layer 11 becomes deposited on the outer surfaces of the antireflection coating 12 that has been etched into a column below the resist pattern 14a and acts so as to suppress further etching of the column part 12a.

Accordingly, when the material of the protective layer 11 acts so as to suppress etching of the column part 12a, even if the processing time of the dry etching is increased by a certain amount, there will be no large fluctuations in the form of the finished resist mask 20.

By using the effect whereby the scattered (i.e., sublimated) protective layer 11 produced by the dry etching suppresses etching of the column parts 12a made up of the antireflection coating 12, it becomes possible to carry out processing by dry etching with a large margin for error, which makes the processing easier.

That is, even if the processing time of the dry etching is increased by a certain amount, it will be possible to avoid the problem of the resist mask 20 collapsing due to the column part 12a becoming too narrow. It also becomes possible to form the resist mask 20 in a predetermined shape without controlling the processing time of the dry etching apparatus especially precisely. Accordingly, there is the advantage that even if there are fluctuations in the etching rate of the dry etching apparatus, the form of the resist mask 20 will not be sensitive to such fluctuations, which makes it easy to control the dry etching apparatus.

As the protective layer 11 that protects the element layer 10, a material such as tantalum or ruthenium is used. According to experimentation, it was found that when tantalum was used as the protective layer 11, there was no significant effect in suppressing the etching of the antireflection coating 12. However, when ruthenium was used as the protective layer 11, there was a sufficient effect in suppressing etching of the antireflection coating 12 which made it possible to form a resist mask 20 of the desired form, thereby eliminating the problem of the resist mask 20 collapsing.

In this way, when carrying out the dry etching process, by using the effect whereby the protective layer 11 suppresses etching of the antireflection coating 12, it becomes possible to improve the manufacturing efficiency of read terminals and to greatly improve the manufacturing yield.

The method of manufacturing according to the present embodiment can form a resist mask without fluctuations and can be used effectively even when read terminals are made finer and higher formation precision becomes required for the resist mask.

FIG. 1E shows a state where a read terminal 10a has been formed by carrying out ion milling of the element layer 10 using the resist mask 20 formed by the method described above. Here, the resist mask 20 acts as a shield for the direction of ion irradiation so that the side surfaces of the square pattern 10a are formed as sloping surfaces. With the resist mask 20, the overhanging parts 14b and the column part 12a are formed with a predetermined precision, so that during the lift-off process, the scattered material adhering to the resist mask 20 is reliably removed together with the resist mask 20, thereby forming a read terminal 10a of a predetermined form.

What is claimed is:

1. A method of manufacturing a pattern, comprising:
a step of forming a layer to be patterned on a substrate;
a step of forming a first mask layer on the layer to be patterned;
a step of forming a second mask layer, which has a lower etching rate during a dry etching process than the first mask layer, on the first mask layer;
a step of exposing and developing the second mask layer to form the second mask layer in a predetermined shape; and
a step of removing exposed parts of the first mask layer that are exposed from the second mask layer by dry etching and dry etching a part of the first mask layer below the second mask layer from sides thereof to form a column part in the first mask layer that is narrower than the second mask layer, thereby forming a mask with overhanging parts.

2. A method of manufacturing a pattern according to claim 1, wherein the first mask layer is made of resin and the second mask layer is made of a resist material including silicon.

3. A method of manufacturing a pattern according to claim 1, wherein a protective layer, which is composed of a material that suppresses etching of the column part made of the first mask layer during the dry etching process, is formed as an uppermost layer of the layer to be patterned.

4. A method of manufacturing a pattern according to claim 3, wherein the protective layer is made of ruthenium.

5. A method of manufacturing a pattern, comprising:
a step of forming a layer to be patterned, whose surface is made of ruthenium, on a substrate;
a step of forming a first mask layer on the layer to be patterned;
a step of forming a second mask layer, which has a lower etching rate than the first mask layer, on the first mask layer;
a step of exposing and developing the second mask layer to form the second mask layer in a predetermined shape; and
a step of removing exposed parts of the first mask layer that are exposed from the second mask layer by etching and etching a part of the first mask layer below the second mask layer from sides thereof to form a column part in the first mask layer that is narrower than the second mask layer, thereby forming a mask with overhanging parts.

6. A method of manufacturing a magnetoresistive effect element, comprising:
a step of forming a magnetoresistive effect film;
a step of forming a first mask layer on the magnetoresistive effect film;
a step of forming a second mask layer, which has a lower etching rate during a dry etching process than the first mask layer, on the first mask layer;
a step of exposing and developing the second mask layer to form the second mask layer in a predetermined shape; and
a step of removing exposed parts of the first mask layer that are exposed from the second mask layer by dry etching and dry etching a part of the first mask layer below the second mask layer from sides thereof to form a column part in the first mask layer that is narrower than the second mask layer, thereby forming a mask with overhanging parts.

7. A method of manufacturing a magnetoresistive effect element, comprising:
a step of forming a magnetoresistive effect film whose surface is formed of ruthenium;
a step of forming a first mask layer on the magnetoresistive effect film;
a step of forming a second mask layer, which has a lower etching rate than the first mask layer, on the first mask layer;
a step of exposing and developing the second mask layer to form the second mask layer in a predetermined shape; and
a step of removing exposed parts of the first mask layer that are exposed from the second mask layer by etching and etching a part of the first mask layer below the second mask layer from sides thereof to form a column part in the first mask layer that is narrower than the second mask layer, thereby forming a mask with overhanging parts.
